(19) United States
(12) Patent Application Publication
(10) Pub. No.: US 2025/0129240 A1
(43) Pub. Date: Apr. 24, 2025

(54) METHOD FOR CURING A CURABLE COMPOSITION

(71) Applicant: Arkema France, Colombes (FR)

(72) Inventors: Jean-Pierre DISSON, PIERRE-BENITE Cedex (FR); Leonard PALYS, KING OF PRUSSIA, PA (US)

(21) Appl. No.: 18/730,362

(22) PCT Filed: Jan. 24, 2023
(86) PCT No.: PCT/EP2023/051692

§ 371 Date: Jul. 19, 2024

(30) Foreign Application Priority Data
Jan. 25, 2022 (FR) FR2200639

(51) Int. Cl. C08L 23/06

(52) U.S. Cl. CPC C08L 23/06; C08L 2207/324; C08L 2312/00

(57) ABSTRACT

The invention relates to a method for curing a curable composition, comprising a step of curing at a temperature of 100° C. or more and in the absence of oxygen, said composition with an organic peroxide formulation comprising a drying oil. The present invention also pertains to articles obtainable by said method.

### TECHNICAL FIELD

The present invention relates to a method for curing a curable composition, comprising a step of curing at a temperature of 100° C. or more and in the absence of oxygen, said composition with an organic peroxide formulation comprising a drying oil. The present invention also pertains to articles obtainable by said method.

### TECHNICAL BACKGROUND

Polymers and copolymers, namely thermoplastic polymers, elastomers and their mixtures, crosslinked with organic peroxides and/or azo compounds generally display better mechanical and physical properties than uncrosslinked polymers or polymers crosslinked by sulfur cure. These properties can include for instance high heat ageing resistance, low percent compression set, decreased staining of metal and easy production of colored products with enhanced color stability.

However, premature crosslinking, also designated as scorching, occurring during the preparatory phase represents a major issue in the implementation of organic peroxides and azo compounds in crosslinking (also called curing) applications of elastomeric and/or thermoplastic materials.

The preparatory phase generally consists in blending or compounding the constituents and possibly extruding them at often high temperatures. The operating conditions of this preparatory phase lead very often to the partial decomposition of the peroxide or azo initiator, thus inducing the premature crosslinking reaction with the formation of gel particles in the mass of the polymeric mixture. The presence of these gel particles is responsible for imparting flaws, such as inhomogeneity and surface roughness, to the final product.

As a result, scorching can scale back the plastic properties of the targeted polymeric material, so that it can no longer be transformed, which may result in the loss of the whole batch. In addition, excessive scorching can lead in some instances to the complete shutdown of the extrusion operation.

Several attempts related in the art have been developed in order to curb the tendency towards scorching. For example, the addition of a free radical initiator whose half-life time is long has already been pushed forward. However, the drawbacks ensuing from this implementation are the low productivity due to a long curing and the high energy costs.

Besides, other attempts hinge on using various additives as scorching inhibitors during the crosslinking of polymeric compositions, such as organic hydroperoxides, vinyl monomers, nitrites, aromatic amines, phenolic compounds, mercaptothiazole compounds, sulfides, hydroquinones, nitroxides and dialkyl dithio-carbamate compounds.

Although these additives are used to extend the time for withstanding scorching, they have the drawback of being based on low molecular weight molecules they can generate volatiles or low molecular weight by-products during the processing or after having reacted.

Accordingly, it remains a real need to provide compositions which are able to extend the scorch resistance time during the crosslinking of a polymeric composition, especially a thermoplastic and/or an elastomeric composition, without inducing a harmful effect on the curing time and/or the final crosslinking density, and that permits to decrease, or even avoid the presence of volatiles or low molecular weight by-products.

In other words, one of the purposes of the present invention is to provide compositions that are able to crosslink (or cure) efficiently polymeric compositions and bestow at the same time good properties, in terms of physical and/or mechanical properties, to the targeted product.

In particular, one of the goals of the invention is to retard scorching during the crosslinking of polymeric compositions without being based on low molecular weight additives.

### SUMMARY OF THE INVENTION

It is a first object of the invention to provide a method for curing a curable composition comprising at least one curable polymer, comprising a step of curing at a temperature of 100° C. or more and in the absence of oxygen, said composition with an organic peroxide formulation comprising:
at least one organic peroxide, and
at least one drying oil,
   wherein the weight ratio of the drying oil to the organic peroxide is lower than or equal to 3.

The method of the present invention allows delaying scorching of said curable composition without significantly impeding the crosslinking density nor the crosslinking speed. Furthermore, the drying oils contain unsaturations that react with the polymeric material to be cross-linked, thus preventing the generation of low molecular weight species.

In some embodiments, the at least one drying oil has an iodine value of from 125 to 215 g/100 g, preferably from 140 to 205 g/100 g, more preferably from 150 to 180 g/100 g. The iodine value is known to be an indirect measurement of the content of unsaturated C═C bonds in a molecule.

In some embodiments, the at least one drying oil has a saponification value of from 175 to 200 mg KOH/g, preferably from 180 to 195 mg KOH/g.

In some embodiments, the at least one drying oil is selected from the group consisting of tung oil, hemp oil, linseed oil, poppy oil, walnut oil, sunflower oil, cottonseed oil, corn oil, soybean oil, fish oils such as sardine oil and cod liver oil, herring oil, safflower oil, flax seed oil, perilla oil, oiticica oil, and combinations thereof, preferably the at least one drying oil is a tung oil.

In some embodiments, the at least one organic peroxide is selected from the group consisting of dialkyl peroxides, diperoxyketals, peroxyketals, monoperoxycarbonates, cyclic ketone peroxides, diacyl peroxides, organosulfonyl peroxides, peroxyesters, peroxydicarbonates and combinations thereof, preferably selected from the group consisting of diperoxyketals, peroxyketals, monoperoxycarbonates peroxyesters and combinations thereof, more preferably selected from the group consisting of OO-t-butyl-O-(2-ethylhexyl)-monoperoxycarbonate, OO-t-butyl-O-2-isopropyl-monoperoxycarbonate, OO-t-amyl-O-(2-ethylhexyl)-monoperoxycarbonate, OO-t-amyl-O-2-isopropyl-monoperoxycarbonate, OO-t-hexyl-O-(2-ethylhexyl)-monoperoxycarbonate and mixtures thereof, optionally in combination with at least one other peroxide.

In some embodiments, the organic peroxide formulation further comprises at least one silane component, preferably selected from the group consisting of vinyltriethoxysilane, vinyltris(2-methoxyethoxy) silane, 3-methacryloxypropyltriethoxysilane, 3-methacryloxypropyltrimethoxysilane, 3-glycidoxypropyltrimethoxysilane, N-2-(aminoethyl)-3-aminopropyltrimethoxysilane, N-2-(aminoethyl)-3-aminopropyltriethoxysilane, 3-mercaptopropyltrimethoxysilane and mixtures thereof, and that is more preferably 3-methacryloxypropyltriethoxysilane or/and 3-methacryloxypropyltrimethoxysilane.

In some embodiments, the organic peroxide formulation further comprises at least one free radical trap selected from the group consisting of nitroxides, quinones and mixtures thereof.

In some embodiments, the weight ratio of the drying oil to the organic peroxide is lower than or equal to 3, more preferably is lower than 2, preferably lower than 0.60, preferably lower than 0.45. More preferably, the weight ratio of the drying oil to the organic peroxide is from 0.025 to 3, preferably from 0.03 to 2, more preferably from 0.03 to 0.6, even more preferably from 0.05 to 0.45, even more preferably from 0.1 to 0.4.

In some embodiments, the organic peroxide formulation further comprises at least one coagent, preferably selected from the group consisting of triallyl cyanurate, triallyl isocyanurate, N,N′-m-phenylene dimaleimide, triallyl trimellitate, trimethylolpropane triacrylate, trimethylolpropane trimethacrylate, trivinyl cyclohexane and mixtures thereof.

In some embodiments, the at least one polymer is an ethylene polymer, in particular a poly(ethylene-vinyl acetate) and/or a polyolefin elastomer.

In some embodiments, the amount of the at least one drying oil is from 0.005 to 10 parts by weight, preferably from 0.01 to 5 parts by weight, more preferably from 0.02 to 1 parts by weight, for 100 parts by weight of the at least one polymer.

The invention also relates to a method as described above for manufacturing an article.

The method according to the invention can enable to manufacture an article having good properties, especially good physical and/or mechanical properties, while ensuring a satisfactory productivity.

Therefore, another aspect of the present invention is directed to an article, in particular a film, obtainable by the method as described above.

The invention also relates to the use of an organic peroxide formulation as defined below, to prevent scorching of a curable composition as defined below.

The present invention enables to meet the abovementioned need. In particular, the invention provides a method making it possible to increase the scorch time and thus to minimize the risk of premature crosslinking.

This is achieved by the presence in the peroxide formulation of a drying oil that is in a specific weight ratio relative to the organic peroxide.

### DETAILED DESCRIPTION

The invention will now be described in more detail without limitation in the following description.

Unless otherwise mentioned, the percentages in the present text are percentages by weight.

In the present text, the amounts indicated for a given species can apply to this species according to all its definitions (as mentioned in the present text), including the narrower definitions.

### Organic Peroxide Formulation

The organic peroxide formulation of the invention comprises at least one organic peroxide.

Preferably, the organic peroxide has a one hour half-life temperature of from 110° C. to 160° C., more preferably has a one hour half-life of from 115° C. to 155° C.

The term “one hour half-life temperature” represents the temperature at which half of the organic peroxide has decomposed in a given time of one hour. Conventionally, the “one hour half-life temperature” is measured in n-decane or n-dodecane.

For examples, the organic peroxide may be selected from the group consisting of dialkyl peroxides, diperoxyketals, peroxyketals, monoperoxycarbonates, cyclic ketone peroxides, diacyl peroxides, organosulfonyl peroxides, peroxyesters, peroxydicarbonates and combinations thereof. More particularly, the organic peroxide may be selected from the group consisting of diperoxyketals, peroxyketals, monoperoxycarbonates, peroxyesters, dialkyl peroxides, and combinations thereof.

For the purposes of the invention, the “diperoxyketals” include the peroxides that contain two peroxides groups (O—O) on at least one same carbon.

Examples of diperoxyketals suitable for the invention are 1,1-di(t-butylperoxy)-3,3,5-trimethylcyclohexane; 1,1-di(t-butylperoxy)cyclohexane; n-butyl 4,4-di(t-amylperoxy) valerate; ethyl 3,3-di(t-butylperoxy) butyrate; 2,2-di(t-amylperoxy) propane; 3,6,6,9,9-pentamethyl-3-ethoxycarbonylmethyl-1,2,4,5-tetraoxacyclononane; n-butyl-4,4-bis(t-butylperoxy)valerate; ethyl-3,3-di(t-amylperoxy)butyrate; and mixtures thereof.

The term “peroxyketal” means a compound of the general formula (R₃)(R₄)C(—OR₁)(—OOR₂), in which:
R₁ represents a linear or branched, preferably C₁-C₁₂, preferably C₁-C₄, and more preferably C₁, alkyl group, or represents a cycloalkyl group with R₂,
R₂ represents a linear or branched, preferably C₁-C₁₂, preferably C₄-C₁₂, and more preferably C₅, alkyl group, or represents a cycloalkyl group with
R₁,
R₃ represents a hydrogen atom or a linear or branched, preferably C₁-C₁₂, more preferably C₄-C₁₂, alkyl group, or represents a cycloalkyl group with R₄,
R₄ represents a hydrogen atom or a linear or branched, preferably C₁-C₁₂, more preferably C₄-C₁₂, alkyl group, or represents a cycloalkyl group with R₃.

Preferably, R₃ forms a cycloalkyl group with R₄.

Preferably, when R₃ is a hydrogen atom, R₄ is a linear or branched, preferably C₁-C₁₂, more preferably C₄-C₁₂, alkyl group.

The peroxyketal according to the invention preferably has the general formula (I) below:

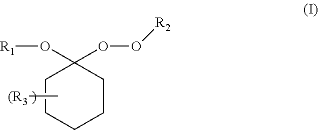

in which formula (I):
   R₁ represents a linear or branched C₁-C₄, preferably C₁, alkyl group,
   R₂ represents a branched C₄-C₁₂, preferably C₅, alkyl group,
   n denotes zero or an integer from 1 to 3,
   R₃ represents a linear or branched C₁-C₃ alkyl group.

R₁ preferably represents a linear, more particularly C₁-C₂, more preferably C₁, alkyl group.

R₂ preferably represents a branched C₄-C₅, more preferably C₅, alkyl group.

Preferably n denotes zero.

R₃ preferably represents a linear or branched, C₁-C₂, more preferably C₁, alkyl group.

Preferably, in the formula (I), R₁ represents a linear or branched, C₁-C₂ alkyl group, R₂ represents a branched C₄-C₅ alkyl group, and n denotes zero.

More preferably still, in the formula (I), R₁ represents a C₁ alkyl group, R₂ represents a branched C₅ alkyl group and n denotes zero.

The organic peroxide or peroxides is or are preferably selected from the group consisting of 1-methoxy-1-tert-amylperoxycyclohexane (TAPMC), 1-methoxy-1-t-butylperoxycyclohexane (TBPMC), 1-methoxy-1-t-amylperoxy-3,3,5-trimethylcyclohexane, 1-methoxy-1-t-butylperoxy-3,3,5-trimethylcyclohexane, 1-ethoxy-1-t-amylperoxycyclohexane, 1-ethoxy-1-t-butylperoxycyclohexane, 1-ethoxy-1-t-butyl-3,3,5-peroxycyclohexane and mixtures thereof.

More preferably still, the organic peroxide according to the invention is 1-methoxy-1-tert-amylperoxycyclohexane (TAPMC).

As peroxyesters useful for the present invention, mention can be made of 2,5-dimethyl-2,5-di(benzoylperoxy) hexane; t-butyl perbenzoate; t-butylperoxy acetate; t-butylperoxy-2-ethyl hexanoate; t-amyl perbenzoate; t-amyl peroxy acetate; t-butyl peroxy isobutyrate; 3-hydroxy-1,1-dimethyl t-butyl peroxy-2-ethyl hexanoate; OO-t-amyl-O-hydrogen-monoperoxy succinate; OO-t-butyl-O-hydrogen-monoperoxy succinate; di-t-butyl diperoxyphthalate; t-butylperoxy (3,3,5-trimethylhexanoate); 1,4-bis(t-butylperoxycarbo)cyclohexane; t-butylperoxy-3,5,5-trimethylhexanoate; t-butyl-peroxy-(cis-3-carboxy) propionate; allyl 3-methyl-3-t-butylperoxy butyrate; and mixtures thereof.

The dialkyl peroxides can be chosen among the group consisting of di-t-butyl peroxide; t-butyl cumyl peroxide; 2,5-di(cumylperoxy)-2,5-dimethyl hexane; 4-methyl-4-(t-butylperoxy)-2-pentanol; 4-methyl-4-(t-amylperoxy)-2-pentanol; 4-methyl-4-(cumylperoxy)-2-pentanol; 4-methyl-4-(t-butylperoxy)-2-pentanone; 4-methyl-4-(t-amylperoxy)-2-pentanone; 4-methyl-4-(cumylperoxy)-2-pentanone; 2,5-dimethyl-2,5-di(t-butylperoxy) hexane; 2,5-dimethyl-2,5-di(t-amylperoxy) hexane; 2,5-dimethyl-2-t-butylperoxy-5-hydroperoxyhexane; 2,5-dimethyl-2-cumylperoxy-5-hydroperoxy hexane; 2,5-dimethyl-2-t-amylperoxy-5-hydroperoxyhexane; 1,3-bis(tert-butylperoxyisopropyl)-benzene, 1,4-bis(tert-butylperoxyisopropyl)-benzene; 1,3,5-tris(t-butylperoxyisopropyl)benzene; 1,3,5-tris(t-amylperoxyisopropyl)benzene; 1,3,5-tris(cumylperoxyisopropyl)benzene; di [1,3-dimethyl-3-(t-butylperoxy)butyl]carbonate; di [1,3-dimethyl-3-(t-amylperoxy)butyl]carbonate; di [1,3-dimethyl-3-(cumylperoxy)butyl]carbonate; di-t-amyl peroxide; dicumyl peroxide; t-butylperoxy-meta-isopropenyl-cumyl peroxide; t-amyl cumyl peroxide; t-butyl-isopropenylcumylperoxide; 2,4,6-tri (butylperoxy)-s-triazine; 1,3,5-tri [1-(t-butylperoxy)-1-methylethyl]benzene; 1,3,5-tri-[(t-butylperoxy)-isopropyl]benzene; 1,3-dimethyl-3-(t-butylperoxy) butanol; 1,3-dimethyl-3-(t-amylperoxy) butanol; and mixtures thereof.

Other dialkyl peroxides which may be used singly or in combination with the other free radical initiators contemplated by the present disclosure are those selected from the group represented by the following formula (I):

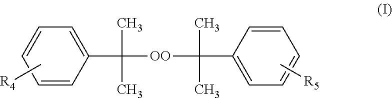

wherein R4 and R5 may independently be in the meta or para positions and are the same or different and are selected from hydrogen or straight or branched chain alkyls of 1 to 6 carbon atoms. Dicumyl peroxide and isopropylcumyl cumyl peroxide are illustrative.

Preferably, the dialkyl peroxides are selected from the compounds having the following formula (II):

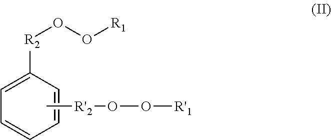

wherein:
   R₁ and R′₁, independently from one another, represent a linear or a branched, preferably branched, alkyl radical C₃-C₁₀,
   R₂ and R′₂, independently from one another, represent a linear or a branched, preferably branched, alkyl radical C₃-C₁₀.

More preferably, according to formula (II):
R₁ and R′₁ are the same and represent a linear or a branched, especially branched, alkyl radical C₃-C₁₀, and
R₂ and R′₂ are the same and represent a linear or a branched, preferably branched, alkyl radical C₃-C₁₀.

Even more preferably, according to formula (II):
R₁ and R′₁ are the same and represent a branched alkyl radical C₃-C₁₀, especially a branched alkyl radical C₃-C₆,
R₂ and R′₂ are the same and represent a branched alkyl radical C₃-C₁₀, especially a branched alkyl radical C₃-C₆.

Preferably, the group R′₂—O—O—R′₁ can be in meta or para position on the benzene ring defined in formula (II).

The dialkyl peroxides corresponding to formula (II) are preferably chosen among the group consisting of 1,3-bis(tert-butylperoxyisopropyl)-benzene, 1,4-bis(tert-butylperoxyisopropyl)-benzene, and their mixture.

The dialkyl peroxides are preferably chosen among the group consisting of 2,5-dimethyl-2,5-di(t-butylperoxy) hexane, dialkyl peroxides represented by formula (I), dialkyl peroxides represented by formula (II) and mixtures thereof.

The dialkyl peroxides are more preferably chosen among the group consisting of 2,5-dimethyl-2,5-di(t-butylperoxy) hexane, dicumyl peroxide, tert-butyl cumyl peroxide, 1,3-bis(tert-butylperoxyisopropyl)-benzene, 1,4-bis(tert-butylperoxyisopropyl)-benzene, and mixtures thereof.

The dialkyl peroxides are even more preferably chosen among the group consisting of 1,3-bis(tert-butylperoxyisopropyl)-benzene, 1,4-bis(tert-butylperoxyisopropyl)-benzene and mixtures thereof.

Imido peroxides may also be used, as such of the type described in PCT application publication WO 97/03961.

Advantageously, the monoperoxycarbonates are selected from the group consisting of OO-t-amyl-O-2-isopropyl-monoperoxycarbonate (TAIC), OO-t-amyl-O-n-propyl monoperoxycarbonate (TAPC), OO-t-butyl-O-2-isopropyl-monoperoxycarbonate (TBIC), t-octyl-isopropyl-monoperoxycarbonate (TOIC), OO-t-hexyl-O-isopropyl-monoperoxycarbonate (THIC),OO-t-amyl-O-(2-ethylhexyl)-monoperoxycarbonate (TAEC), OO-t-butyl-O-(2-ethylhexyl)-monoperoxycarbonate (TBEC),OO-t-octyl-O-(2-ethylhexyl)-monoperoxycarbonate (TOEC), OO-t-hexyl-O-(2-ethylhexyl)-monoperoxycarbonate (THEC) and mixtures thereof. More preferably, the organic peroxide is selected from the group consisting of OO-t-butyl-O-(2-ethylhexyl)-monoperoxycarbonate (TBEC), OO-t-butyl-O-2-isopropyl-monoperoxycarbonate (TBIC), OO-t-amyl-O-(2-ethylhexyl)-monoperoxycarbonate (TAEC), OO-t-amyl-O-2-isopropyl-monoperoxycarbonate (TAIC), OO-t-hexyl-O-(2-ethylhexyl)-monoperoxycarbonate (THEC) and mixtures thereof. These monoperoxycarbonates may optionally be used in combination with at least one another peroxide, such as those mentioned above (for example t-butylperoxy 2-ethylhexanoate).

Even more preferred monoperoxycarbonates are TBEC, TAEC, THEC, or a mixture thereof, optionally in combination with at least one another peroxide, such as those mentioned above (for example a dialkylperoxide or a diperoxyketal). Most preferred organic peroxides are TBEC, TAEC or a mixture thereof, optionally in combination with at least one another peroxide, such as those mentioned above (for example a dialkylperoxide or a diperoxyketal).

The organic peroxide may be present in the formulation in an amount of from 40 to 99% by weight, based on the total weight of the organic peroxide formulation. Preferably, the organic peroxide is present in the formulation in an amount of from 50 to 98% by weight, even more preferably from 60 to 97% by weight, based on the total weight of the organic peroxide formulation.

The organic peroxide formulation of the invention also comprises a least one drying oil. By “drying oil” is meant an oil having an iodine value higher that 110 g/100 g, as measured according to standard GB/T5532-2008. Any drying oils known to the skilled person can be employed in the organic peroxide formulation of the present invention. Drying oils may include oils derived from plant, animal, and fish sources including, for example, glycerol triesters of fatty acids which are characterized by relatively high levels of polyunsaturated fatty acids, especially eleostearic acid and alpha-linolenic acid. Advantageously, the at least one drying oil is selected from the group consisting of tung oil, hemp oil, biofene or trans-beta-farnesene (e.g. the one made by Amyris), linseed oil, poppy oil, walnut oil, sunflower oil, cottonseed oil, corn oil, soybean oil, fish oils such as sardine oil and cod liver oil, herring oil, safflower oil, flax seed oil, perilla oil, oiticica oil, and combinations thereof preferably from the group consisting of tung oil, hemp oil, linseed oil, poppy oil, walnut oil, sunflower oil, cottonseed oil, corn oil, soybean oil, fish oils such as sardine oil and cod liver oil, herring oil, safflower oil, flax seed oil, perilla oil, oiticica oil, and combinations thereof.

More preferably, the drying oil comprises, consists essentially of, or consists of, tung oil, linseed oil, fish oils, in particular cod liver oil, walnut oil, oiticica oil, poppy oil. Most preferably the drying oil comprises, consists essentially of, or consists of, tung oil or linseed oil, and in particular tung oil.

The above-mentioned oil may be modified or not. It may be a virgin oil or a refined oil.

The drying oil used in the formulation of the invention has preferably an iodine value of from 125 to 215 g/100 g, preferably from 140 to 205 g/100 g, more preferably from 150 to 180 g/100 g. The iodine value may be measured according to standard GB/T5532-2008.

The drying oil can have a saponification value of from 175 to 210 mg KOH/g, preferably from 182 to 195 mg KOH/g.

The peroxide formulation advantageously contains the drying oil in an amount of from 1 to 35% by weight, based on the total weight of the organic peroxide formulation. More preferably, the organic peroxide formulation of the invention comprises the drying oil in an amount of from 2 to 25% by weight, more preferably from 3 to 20% by weight, even more preferably from 5 to 15% by weight, based on the total weight of the organic peroxide formulation.

The weight ratio of the drying oil to the organic peroxide in the organic peroxide formulation is lower than or equal to 3, more preferably is lower than 2, preferably lower than 0.60, preferably lower than 0.45. More preferably, the weight ratio of the drying oil to the organic peroxide is from 0.025 to 3, preferably from 0.03 to 2, more preferably from 0.03 to 0.6, even more preferably from 0.05 to 0.45, even more preferably from 0.1 to 0.4.

When two or more organic peroxides are present in the organic peroxide formulation, the weight ratio of the drying oil to the organic peroxide is based on the total weight of the organic peroxides.

When two or more drying oils are present in the organic peroxide formulation, the weight ratio of the drying oils to the organic peroxide is based on the total weight of the drying oils.

The organic peroxide formulation may also comprise a silane component. The silane component has a scorch-protecting effect and makes it possible to further increase the scorch time. The silane component may further act as a coupling agent, the silane component making it possible to improve the adhesion properties of the polymer composition in which the peroxide formulation is used.

In some embodiments, the silane component may be a silane component with an amino functionality, a silane component with a sulfur functionality, a silane component with an epoxy functionality, a silane component with a (meth)acryl functionality, a silane component with a chloro functionality and/or a silane component with a vinylyl functionality.

The amount of silane component in the organic peroxide formulation is advantageously of from 5 to 50% by weight, preferably from 10 to 50% by weight, more preferably from 20 to 40% by weight, based on the total weight of the organic peroxide formulation.

The weight ratio of the silane component to the organic peroxide is preferably from 0.1 to 1, more preferably from 0.3 to 0.7.

When two or more organic peroxides are present in the organic peroxide formulation, the weight ratio of the silane component to the organic peroxides is based on the total weight of the organic peroxides.

When two or more silane components are present in the organic peroxide formulation, the weight ratio of silane components to the organic peroxide is based on the total weight of the silane components.

The organic peroxide formulation may consist essentially of, or consist of, the at least at least one organic peroxide and the at least one drying oil.

Alternatively, organic peroxide formulation may consist essentially of, or consist of, the at least at least one organic peroxide, the at least one drying oil and the at least one silane component.

Alternatively, the organic peroxide formulation may further comprise a coagent (which is not an organic peroxide). Advantageously, said coagent bears at least one carbamate, maleimide, acrylate, methacrylate or allyl functional group. Allyl carboxylates may be used, which may be selected in the group consisting of the allyl, diallyl and triallyl type.

The coagent may be chosen from the group consisting of divinylbenzene, diisopropenyl benzene, alpha methylstyrene, alpha-methylstyrene dimer, ethylene glycol dimethacrylate, phenylene dimethacrylate, diethylene glycol dimethacrylate, triethylene glycol dimethacrylate, tetraethylene glycol dimethacrylate, polyethylene glycol 200 dimethacrylate, polyethylene glycol 400 dimethacrylate, 1,3-butanediol dimethacrylate, 1,4-butanediol dimethacrylate, 1,6-hexanediol dimethacrylate, 1,12-dodecanediol dimethacrylate, 1,3-glycerol dimethacrylate, diurethane dimethacrylate, trimethylolpropane trimethacrylate, bisphenol A epoxy diacrylate, dipropylene glycol diacrylate, tripropylene glycol diacrylate, polyethylene glycol 600 diacrylate, ethylene glycol diacrylate, diethylene glycol diacrylate, triethylene glycol diacrylate, tetraethylene glycol diacrylate, neopentyl glycol ethoxylate diacrylate, butanediol diacrylate, hexanediol diacrylate, aliphatic urethane diacrylate, trimethylolpropane triacrylate, trimethylolpropane ethoxylate triacrylate, trimethylolpropane propoxylate triacrylate, glycerol propoxylate triacrylate, aliphatic urethane triacrylate, dipentaerythritol pentaacrylate, triallyle cyanurate (TAC), triallyle isocyanurate (TAIC), triallyl trimellitate, N,N′-m-phenylene dimaleimide, butadiene, chloroprene, isoprene, trivinylcyclohexane and mixtures thereof.

More preferably, the coagent is selected from the group consisting of triallyl cyanurate, triallyl isocyanurate, N,N′-m-phenylene dimaleimide, triallyl trimellitate, trimethylolpropane triacrylate, trimethylolpropane trimethacrylate, trivinylcyclohexane and mixtures thereof, even more preferably is selected from the group consisting of triallyl cyanurate (TAC), triallyl isocyanurate (TAIC), trimethylolpropane triacrylate (TMPTA), trimethylolpropane trimethacrylate (TMPTMA) and mixtures thereof, and most preferably is triallyl isocyanurate (TAIC).

The main purpose of using a coagent is to increase the level of crosslinking of the polymer cured using the formulation of the invention. The coagent also makes it possible to reduce residual gas emission during the decomposition of the peroxides, and to ultimately reduce the number of bubbles in the encapsulating film.

The weight ratio of the coagent to the organic peroxide is preferably from 0.1 to 10, more preferably from 0.3 to 3, even more preferably from 0.4 to 1.

When two or more organic peroxides are present in the organic peroxide formulation, the weight ratio of the coagent to the organic peroxide is based on the total weight of the organic peroxides.

When two or more coagents are present in the organic peroxide formulation, the weight ratio of coagents to the organic peroxide is based on the total weight of the coagents.

In some embodiments, the organic peroxide formulation may consist essentially of, or consist of, the at least at least one organic peroxide, the at least one drying oil, the at least one silane component and the at least one coagent.

In other embodiments, the organic peroxide formulation may comprise one or more other additives, preferably chosen from the group consisting of the UV stabilizers, the UV absorbers, the coupling agents, the fillers, the plasticizers, the flame retardants, the antioxidants, the dyes and pigments, the free radical traps and mixtures thereof. UV stabilizers may be chosen among hindered amine light stabilizers (HALS). UV absorbers may be selected, for instance, from benzophenones, triazines and benzotriazoles. UV stabilizers and UV absorbers may be present in the organic peroxide formulation in a weight ratio relative to the organic peroxide of from 0.0005 to 0.01. As examples of coupling agents (other than the silane components described above), mention can be made of monoalkyl titanates. Inorganic fillers such as silicon dioxide, alumina, talc, calcium carbonate may be added to increase mechanical strength of the polymeric material once crosslinked using the present peroxide formulation, although nanometric clays are preferred because of the transparency they provide. Examples of plasticizers are paraffinic or aromatic mineral oils, phthalates, azelates, adipates and the like. Antioxidants may be phenolic, phosphate or sulfur antioxidants. Alternatively or additionally, quinolines such as 1,2-dihydro-2,2,4-trimethylquinoline, may be used as an antioxidant. Organic or mineral pigments may also be added for coloring the polymer composition in which the formulation is intended to be used. Mention can be made in particular of titanium dioxide, which makes it possible to produce a white color, which may be particularly useful when the formulation is used in a polymer composition employed for manufacturing a film intended to be used at the rear face of photovoltaic modules. Examples of free radical traps suitable for the present invention are those selected from the group consisting of nitroxides (in particular 4-hydroxy-TEMPO) and quinones. As used herein, the term “quinone” includes both quinones and hydroquinones. Non-limiting examples of quinones that may be used in formulations of the present invention include mono-tert-butylhydroquinone (MTBHQ), hydroquinone, hydroquinone mono-methyl ether (HQMME) also known as 4-methoxy phenol, mono-t-amyl hydroquinone, hydroquinone bis(2-hydroxyethyl) ether, 4-ethoxy phenol, 4-phenoxy phenol, 4-(benzyloxy) phenol, 2,5-bis(morpholinomethyl) hydroquinone and benzoquinone.

The organic peroxide formulation may consist essentially of, or consist of, the at least at least one organic peroxide, the at least one drying oil, the at least one silane component, the at least one coagent and optionally one or more additives selected from the group consisting of UV stabilizers, UV absorbers, coupling agents, fillers, plasticizers, flame retardants, antioxidants, dyes and pigments, free radical traps and combinations thereof.

The organic peroxide formulation may comprise free radical traps selected from the group consisting of nitroxides, quinones and mixtures thereof.

The organic peroxide formulation may comprise free radical traps in a weight ratio of the free radical traps to the organic peroxide from 0 to 0.5, more preferably from 0 to 0.15, even more preferably from 0 to 0.05, even more preferably from 0 to 0.002.

The organic peroxide formulation may comprise a total amount of nitroxide and quinone free radical traps in a weight ratio relative to the organic peroxide of from 0 to 0.5, more preferably from 0 to 0.15, more preferably from 0 to 0.05, even more preferably from 0 to 0.002.

When two or more organic peroxides are present in the organic peroxide formulation, the weight ratio of the free radical traps to the organic peroxide is based on the total weight of the organic peroxide.

In some advantageous embodiments, the organic peroxide formulation does not comprise (i.e. is devoid of) 4-hydroxy TEMPO and/or MTBHQ, and more particularly, does not comprise nitroxides and/or quinones free radical traps.

The organic peroxide formulation may be devoid of any free radical trap.

The curable composition comprises at least one curable polymer, preferably chosen among the group consisting of thermoplastic polymer, elastomeric polymer and mixture thereof.

By “curable composition/polymer”, it is meant that the composition/the polymer can be cured (or crosslinked).

The thermoplastic and/or elastomeric polymers taken into consideration in the present invention may be defined as natural or synthetic polymers which have a thermoplastic and/or elastomeric character and which may be crosslinked (cured) under the action of a cross-linking agent. The crosslinking action and crosslinkable polymers are described in Rubber World, “Elastomer Crosslinking with Diperoxyketals”, October 1983, pages 26-32, and in Rubber and Plastic News, “Organic Peroxides for Rubber Crosslinking”, 29 Sep. 1980, pages 46-50. Polyolefins which are suitable for the present invention are described in Modern Plastics Encyclopedia 89, pages 63-67, 74-75.

The polymer can be selected in the group consisting of low density linear polyethylene (LLDPE), low density polyethylene (LDPE), high density polyethylene, ethylene-propylene copolymers (EPM), polypropylene, ethylene-propylene-diene terpolymers (EPDM), ethylene-vinyl acetate copolymers (EVA), ethylene-alpha olefin copolymers (in particular, polyolefin elastomers (POE)), ethylene-butylacrylate copolymers (EBA), ethylene-methylacrylate copolymers (EMA), ethylene-ethylacrylate copolymers (EBA), silicone rubber, natural rubber (NR), polyisoprene (IR), polybutadiene (BR) acrylonitrile-butadiene copolymers (NBR), styrene-butadiene copolymers (SBR), neoprene rubber (CR), acrylonitrile-butadiene-styrene (ABS), styrene-butadiene-styrene block copolymers (SBS), chlorinated polyethylene (CPE), chlorosulfonated polyethylene, fluoroelastomers, ethylene-methyl (meth)-acrylate copolymers and ethylene-glycidyl methacrylate copolymers, biopolymers, and mixtures thereof.

The preferred biopolymers are chosen in the group consisting of polylactic acid (PLA), polyglycolic acid (PGA), poly-£-caprolactone (PCL), polyhydroxybutyrate (PHB), polybutylene adipate terephthalate (PBAT), and poly(3-hydroxy valerate), copolymers thereof and mixtures thereof.

Preferably, the polymers do not contain olefinic double bonds in the backbone or in the lateral chains.

Preferably, the polymer can be selected in the group consisting of low density linear polyethylene (LLDPE), low density polyethylene (LDPE), high density polyethylene (HDPE), ethylene-propylene copolymers (EPM), polypropylene, ethylene-vinyl acetate copolymers (EVA), ethylene-alpha olefin copolymers (in particular, polyolefin elastomers (POE)), ethylene-butylacrylate copolymers (EBA), ethylene-methylacrylate copolymers (EMA), ethylene-ethylacrylate copolymers (EBA), silicone rubber, chlorinated polyethylene (CPE), chlorosulfonated polyethylene, fluoroelastomers, ethylene-methyl (meth)-acrylate copolymers and ethylene-glycidyl methacrylate copolymers, biopolymers and combinations thereof.

Preferably, the polymer can be chosen in the group consisting of an ethylenic copolymer, and more preferably ethylene-vinyl acetate copolymers (EVA), low density polyethylene (LDPE), polyolefin elastomers (POE), high density polyethylene (HDPE), and combinations thereof.

The EVA copolymer may comprise from 15 to 60% by weight, preferably from 25 to 45% by weight, of units derived from vinyl acetate (VA) monomers. Examples of such EVA copolymers are available under the trade name “Evatane® 18-150” and “Evatane® 40-55” from ARKEMA.

Other ethylene polymers that may be used in the invention have been disclosed, e.g., in EP 2242647. They comprise a functionalized polyolefin, such as a homopolymer of ethylene or a copolymer of ethylene with an alkyl (meth)acrylate or vinyl acetate, which may be functionalized either by grafting of by copolymerization with maleic anhydride or glycidyl methacrylate. This functionalized polyolefin may optionally be mixed with a copolymer of ethylene/carboxylic acid vinyl ester such as EVA.

Alternatively, or additionally, the polymer may advantageously be a polyolefin elastomer (comprising units derived from ethylene or not).

A “polyolefin” in the sense of the present invention means a polymer derived from an olefin, for example ethylene, propylene, butene, hexene, etc.

By “derived from [a monomer]”, it is meant that the polymer comprises in its main chain and/or in its adjacent chains (or pendant chains) units resulting from the polymerization or copolymerization of at least said monomer.

Preferably, the at least one organic peroxide is present in the curable composition in an amount of from 0.05 to 20 parts by weight for 100 parts by weight of polymer (preferably, of ethylene polymer). More preferably, the organic peroxide is present in an amount of from 0.1 to 3 parts by weight, even more preferably from 0.3 to 1.5 parts by weight, even more preferably from 0.3 to 1.3 parts by weight, for 100 parts by weight of polymer.

The at least one drying oil may advantageously be present in the curable composition in an amount of from 0.005 to 10 parts by weight for 100 parts by weight of polymer (preferably, of ethylene polymer), preferably from 0.01 to 5 parts by weight, even more preferably from 0.02 to 1 parts by weight, even more preferably from 0.02 to 0.5 parts by weight, such as from 0.02 to 0.3 parts by weight, for 100 parts by weight of polymer.

When present, the at least one silane component may preferably be present in the curable composition in an amount of from 0.01 to 20 parts by weight for 100 parts by weight of polymer (preferably, of ethylene polymer), more preferably from 0.05 to 5 parts by weight, even more preferably from 0.1 to 1 parts by weight, for 100 parts by weight of polymer.

When present, the at least one coagent may be included in the curable composition in an amount of from 0.005 to 10 parts by weight, preferably from 0.01 to 5 parts by weight, more preferably from 0.05 to 2 parts by weight, even more preferably from 0.1 to 1 parts by weight, for 100 parts by weight of polymer (preferably, of ethylene polymer).

Other additives, preferably chosen from the UV stabilizers, the UV absorbers, the coupling agents, the fillers, the plasticizers, the flame retardants, the antioxidants, the dyes and pigments, the free radical traps and mixtures thereof, may be present in the polymer composition.

The curable composition of the invention may consist essentially of, or consist of, the at least one polymer (preferably an ethylene polymer), the at least one organic peroxide, the at least one drying oil, optionally the at least one silane component, optionally the at least one coagent, and optionally the additives (preferably selected from the group consisting of the UV stabilizers, the UV absorbers, the coupling agents, the fillers, the plasticizers, the flame retardants, the antioxidants, the dyes and pigments, the free radical traps and mixtures thereof).

In some embodiments, the curable composition is devoid of 4-hydroxy TEMPO and/or MTBHQ, and more particularly, is devoid of nitroxides and/or quinones free radical traps. The polymer composition may be devoid of free radical traps.

The curing step is advantageously carried out at a temperature of 110° C. or more, preferably at a temperature of from 120 to 250° C., more preferably from 130 to 180° C., even more preferably from 130 to 165° C. The curing step may last from 4 to 50 minutes, preferably from 6 to 35 minutes.

By the expression “in the absence of oxygen”, it is meant that the curable composition is at least not intentionally in contact with oxygen during the curing step. In other words, the curable composition is substantially not in the presence of oxygen during the curing step, and preferentially the curable composition is not in the presence of oxygen during the curing step. Not limited to the following conditions, the absence of oxygen can for example occur when the rubber is cured by press moulding or injection moulding in between metallic plates, in lamination between two other materials, when the composition is cured in an autoclave that has been purged from air and maintained under nitrogen or vacuum during the curing stage, or when it is cured in a molten salts bath after rubber extrusion.

Consequently the curing step can be carried out by a method chosen in the group consisting of press moulding, injection moulding, lamination, curing in an autoclave that has been purged from air and maintained under nitrogen or vacuum during the curing stage and curing in a molten salts bath.

Preferably, the curing step is not performed with a hot air oven, a hot air tunnel or a not air-purged steam autoclave. Said equipment require the presence of air in the system, which is not desired in the method of the invention.

Preferably, the method also comprises a step of shaping the curable composition. This step may be performed prior to and/or simultaneously with the curing step. Advantageously, the step of shaping the polymer composition is selected from a step of molding, a step of extruding, and a step of injection-molding the polymer composition.

Preferably, the step of shaping the polymer composition is carried out prior to the step of curing the polymer composition. Thus, preferably, no curing or substantially no curing occurs during the shaping step. When the shaping step is performed prior to the curing step, said shaping step may be carried out at a temperature of from 80 to 150° C., more preferably from 90 to 120° C. Alternatively, the shaping step and the curing step may be conducted in a single step.

The method of the invention can include a step a′) of mixing the at least one organic peroxide and the at least one drying oil and optionally the other components of the formulation (such as the at least one coagent and/or the other additives).

The mixing step may be carried out in one or more steps (some of the components may thus be premixed before being mixed with the other components of the formulation). The mixing step can be performed using any kind of equipment adapted for mixing formulations containing mostly liquid.

The mixing step is preferably carried out at a temperature below the decomposition temperature of the organic peroxide. It may be carried out at a temperature of from −10° C. to 50° C., preferably from 10° C. to 40° C.

The method of the invention can include a step a″) of mixing the at least one polymer and the organic peroxide formulation as described above. The polymer may be mixed with an organic peroxide formulation previously prepared, or may be mixed, in one or more steps, with any or each of the components of the organic peroxide formulation, and/or any premix of components of the organic peroxide formulation.

In other words, the method of the invention can comprise a step a′) of preparation of the organic peroxide formulation as described above followed by a step a″) of mixing the at least one polymer as described above and the organic peroxide formulation obtained in step a′). Alternatively, said step a′) and a″) can be done simultaneously.

The mixing step(s) may be carried out in any conventional device, such as in a continuous mixer, a batch mixer, a compound extruder, a two-roll mill, or directly in the barrel of a film extrusion line. The temperature of the mixing step is preferably below the decomposition temperature of the peroxide. In particular, the mixing step may be carried out at a temperature ranging from −10 to 120° C., preferably from 10 to 120° C.

Preferably, when the organic peroxide is a liquid or can be dissolved in other additives of the composition, the method also comprises an impregnation step after the mixing step a″). In such an impregnation step, the polymer, preferably in the form of pellets, is left to rest after being mixed with the peroxide organic formulation, preferably for at least 1 h, so that the organic peroxide impregnates the polymer pellets.

In the above methods, the components and their amounts may be as described in the previous sections.

### Applications

Another object of the invention is the use of an organic peroxide formulation as described above for curing, in the absence of oxygen, a curable composition. Preferably, the curable composition is as defined above.

Preferably, the composition is curable at a temperature of 100° C. or more, preferably at a temperature of 110° C. or more, more preferably at a temperature of 120 to 250° C., more preferably from 130 to 180° C., more preferably from 130 to 165° C.

The invention also relates to the method as described above for manufacturing an article.

In some embodiments, the produced article is a film (or a sheet). In such embodiments, the method comprises a step of shaping the polymer composition so as to form a film. Said step may be carried out using a T-die extruder or, as alternatively, using a twin-screw extruder coupled to a two-roll mill.

The film may for example have a thickness of from 50 to 2000 μm, preferably from 100 to 1000 μm.

The article manufactured by the above-described method may advantageously be selected from the group consisting of encapsulating materials, particularly encapsulants for solar cells, wire and cable insulations, pipes and hoses (including those for automobile radiators, potable water, and underfloor heating, for example), roller coatings, rotational moldings, cellular articles, and shoe soles.

Most preferably, the article is an encapsulating material and more particularly an encapsulant for solar cells.

The invention also relates to an article obtainable by, or obtained by, the method as described above. The article may be as described above.

A further object of the invention is a photovoltaic module comprising an article as described above, preferably a film as described above.

Another subject-matter of the invention aims at the use of an organic peroxide formulation as defined above, to prevent scorching of a curable composition as defined above.

### EXAMPLES

The following examples illustrate the invention without limiting it.

### Example 1

A first basic composition was prepared by mixing a POE polymer (14 MI, ENGAGER from DOW Chemical Company), 0.75 phr of OO-t-butyl-O-2-ethylhexyl-monoperoxycarbonate (TBEC) (Luperox® TBEC from Arkema), 0.3 phr of 3-methacryloxypropyltrimethoxysilane (KH-570 from Sigma-Aldrich) and 0.5 phr of triallyl isocyanurate (TAIC) (from Ourchem) in a 125 mL bottle. The mixture was then heated for 7.5 hours at 40° C. in an oven. During the heating step, the mixture needed to be shaken every 2-3 hours.

Phr means “parts per hundred rubber”, and thus, in the present example, means “parts by weight for 100 parts of polymer POE”.

OO-t-butyl-O-2-ethylhexyl-monoperoxycarbonate has a one hour half-life temperature of 121° C.

A second basic composition was prepared in the same manner as the first basic composition except that 0.75 phr of OO-tert-amyl O-(2-ethylhexyl) monoperoxycarbonate (TAEC) (Luperox® TAEC, available from Arkema) was used instead of 0.75 phr of TBEC.

OO-tert-amyl O-(2-ethylhexyl) monoperoxycarbonate has a one hour half-life temperature of 117° C.

To these basic compositions, a certain amount of tung oil (from Anhui Refined Oil and Fat CO., Ltd), of an odorless mineral spirit (synthetic iso-paraffin hydrocarbon, from Idemitsu kosan Co. Ltd.) or of refined tung oil (from Anhui Refined Oil and Fat CO., Ltd) was added, as indicated in the table below. The tung oil used in the examples has a saponification value of 193 (determined according to GB/T5534-1995) and an iodine value of 167 g/100 g (determined according to GB/T5532-2008).

TABLE 1

| | | | | |
|---|---|---|---|---|
| | | | | oil/organic |
| | | Refined | | peroxide |
| Composition | Tung oil | tung oil | Mineral | weight |
| No. | (phr) | (phr) | spirit (phr) | ratio |

Peroxide = TBEC

| | | | | |
|---|---|---|---|---|
| 1 | — | — | — | |
| 2 | — | — | 0.1125 | 0.15 |
| 3 | 0.0375 | — | — | 0.05 |
| 4 | 0.075 | — | — | 0.1 |
| 5 | 0.1125 | — | — | 0.15 |
| 6 | — | 0.0375 | — | 0.05 |
| 7 | — | 0.075 | — | 0.1 |

Peroxide = TAEC

| | | | | |
|---|---|---|---|---|
| 8 | — | — | — | |
| 9 | 0.1125 | — | — | 0.15 |

Compositions No. 3, 4, 5, 6, 7 and 9 are compositions according to the invention; compositions No. 1, 2 and 8 are comparative compositions. Compositions No. 1 to 7 comprise TBEC as the organic peroxide; compositions 8 and 9 comprise TAEC as the organic peroxide.

Samples of about 2 to 3 g of the thus produced compositions were deposited in a plate on a Rubber Process Analyser (RPA), of the model type EKT-2003RPA-N from EKTRON TEK. CO., LTD, which is able to measure the cure properties of the samples and includes a software for analyzing the results. Each of the samples was placed in a temperature-controlled cavity between two plates, the lower of which oscillates to apply a cyclic stress or strain to the sample while the upper die is connected to a torque sensor to measure the torque response of the sample to the deformation. Under these conditions, the surfaces of the sample are protected against the presence of air (and thus oxygen) by the metallic surfaces of the plates. The stiffness is recorded continuously as a function of time. The stiffness of the sample increases as crosslinking proceeds.

The RPA is able to provide, inter alia, calculated values of M_{L} (minimum torque), M_{H} (maximum torque), t_{S1} (time to attain an increase of 1 dN·m in torque starting from the minimum torque) and tc₉₀ (time to attain 90% of the M_{H}−M_{L} cure state) as defined by International Standards (such as ASTM D5289). T_{S1} represent the scorch time. From these data, the relative degree of crosslinking MH-ML (or crosslinking density) can be determined.

The RPA was operated at 145° C. with an oscillation amplitude (deformation degree) of 0.5°, an oscillation frequency of 1.667 and strain value of 7 applied to the sample for 30 min, except for examples 10 and 11 where the test was carried for 45 minutes.

The results are set forth in the table below.

TABLE 2

| | | | |
|---|---|---|---|
| Composition No. | Tₛ₁ (s) | M_{H}-M_{L} (dN · m/s) | T_{c90} (s) |

Peroxide = TBEC (RPA test 30 min)

| | | | |
|---|---|---|---|
| 1 | 411 | 2.59 | 1136 |
| 2 | 418 | 2.53 | 1163 |
| 3 | 433 | 2.56 | 1153 |
| 4 | 446 | 2.56 | 1181 |
| 5 | 471 | 2.55 | 1218 |
| 6 | 419 | 2.50 | 1150 |
| 7 | 436 | 2.51 | 1161 |

Peroxide = TAEC (RPA test 45 min)

| | | | |
|---|---|---|---|
| 8 | 240 | 2.34 | 772 |
| 9 | 268 | 2.50 | 824 |

The compositions of the invention, that comprise tung oil, lead to a longer scorch time compared to the compositions comprising no oil or comprising a mineral spirit. Thus, tung oil is effective as a scorch-protecting agent. In addition, the crosslinking density obtained with the compositions of the invention is not impaired and the tc₉₀ remains within an acceptable range. This conclusion is true regardless of the used peroxide. Moreover, it can be seen that refined tung oil acts as an effective scorch-protecting agent as well.

### Example 2

A first basic composition was prepared by mixing an EVA polymer (V2825 from JiangSu Sailboat Petrochemical), 0.6 phr of TBEC (Luperox TBEC® from Arkema), 0.3 phr of 3-methacryloxypropyltrimethoxysilane (KH-570 from Sigma-Aldrich) and 0.5 phr of TAIC (from Ourchem) in a 125 ml bottle. The mixture was then heated for 6.5 h at 40° C. in an oven. During the heating step, the mixture needed to be shaken every 2-3 hours.

In the present example, phr means “parts by weight for 100 parts of polymer EVA”.

Another basic composition was prepared in the same manner except that 0.6 phr of OO-tert-amyl O-(2-ethylhexyl) monoperoxycarbonate (TAEC) (Luperox® TAEC, available from Arkema) was used instead of 0.6 phr of TBEC.

Yet another basic composition was prepared in the same manner as the first basic composition, except that 1.2 phr of TAEC (Luperox® TAEC) was used instead of 0.6 phr of TBEC.

Yet another basic composition was prepared in the same manner as the first basic composition, except that 1.2 phr of a mixture of 90% by weight of TAEC (Luperox® TAEC) and 10% by weight of t-butylperoxy 2-ethylhexanoate (TBPO) (Luperox® 26 from Arkema) was used instead of 0.6 phr of TBEC.

t-butylperoxy 2-ethylhexanoate has a one hour half-life temperature of 95° C.

Yet another basic composition was prepared in the same manner as the first basic composition, except that 0.75 of TBEC was used instead of 0.6 phr of TBEC.

To each of these compositions, tung oil or castor oil (Castor oil from ADANI) was added or not, as indicated in the following table.

The castor oil, has a saponification index of 180 mg KOH/g and a iodine value of 85 g/100 g determined as described above.

TABLE 3

| Composition | | Tung oil | Castor oil | oil/peroxide |
|---|---|---|---|---|
| No. | Peroxide | (phr) | (phr) | weight ratio |
| 10 | TBEC (0.6 phr) | — | | |
| 11 | TBEC (0.6 phr) | 0.09 | | 0.15 |
| 12 | TAEC (0.6 phr) | — | | |
| 13 | TAEC (0.6 phr) | 0.09 | | 0.15 |
| 14 | TAEC (1.2 phr) | — | | |
| 15 | TAEC (1.2 phr) | 0.1 | | 0.08 |
| 16 | 90% TAEC + 10% | — | | |
| | TBPO (1.2 phr) | | | |
| 17 | 90% TAEC + 10% | 0.1 | | 0.08 |
| | TBPO (1.2 phr) | | | |
| 18 | TBEC (0.75 phr) | — | | |
| 19 | TBEC (0.75 phr) | 0.1125 | | 0.15 |
| 20 | TBEC (0.75 phr) | | 0.1125 | 0.15 |

Compositions No. 11, 13, 15, 17 and 19 are compositions according to the invention; compositions No. 10, 12, 14, 16, 18 and 20 are comparative compositions.

The crosslinking properties of compositions No. 10 to 13 were determined as described in example 1, with a curing time of 30 min.

The crosslinking properties of compositions No. 14 to 17 were determined as described in example 1 but at three different temperatures: at 145° C., at 130° C. and at 110° C. The RPA measurement was carried out for 45 min. Temperatures of 145 and 130° C. simulate the conditions of a lamination process (for example, for manufacturing a photovoltaic module); temperature of 110° C. simulate the conditions of an extrusion process (for example, for forming a film before a lamination process).

The crosslinking properties of compositions No. 18 to 20 were determined as described in example 1 with a curing time of 45 min.

The results are shown in the table below.

TABLE 4

| | | | | |
|---|---|---|---|---|
| Composition | Temperature | | M_{H}-M_{L} | |
| No. | (° C.) | Tₛ₁ (s) | (dN · m/s) | T_{c90} (s) |

Curing time = 30 min

| | | | | |
|---|---|---|---|---|
| 10 | 145 | 235 | 3.99 | 871 |
| 11 | 145 | 335 | 4.03 | 1172 |
| 12 | 145 | 159 | 3.74 | 589 |
| 13 | 145 | 197 | 3.72 | 592 |

Curing time = 45 min
Operating temperature of the RPA = 145° C.

| | | | | |
|---|---|---|---|---|
| 14 | 145 | 100 | 4.37 | 412 |
| 15 | 145 | 109 | 4.38 | 430 |
| 16 | 145 | 99 | 4.09 | 383 |
| 17 | 145 | 108 | 4.31 | 447 |
| 18 | 145 | 237 | 4.13 | 896 |
| 19 | 145 | 292 | 4.04 | 1089 |
| 20 | 145 | 231 | 3.81 | 875 |

Operating temperature of the RPA = 130° C.

| | | | | |
|---|---|---|---|---|
| 14 | 130 | 318 | 3.95 | 1099 |
| 15 | 130 | 373 | 3.95 | 1188 |
| 16 | 130 | 290 | 3.75 | 1071 |
| 17 | 130 | 362 | 3.93 | 1158 |

Operating temperature of the RPA = 110° C.

| | | | | |
|---|---|---|---|---|
| 14 | 110 | ND | 0.83 | Not relevant |
| 15 | 110 | ND | 0.38 | Not relevant |
| 16 | 110 | 1726 | 1.1 | Not relevant |
| 17 | 110 | ND | 0.42 | Not relevant |

ND = not determinable. This indicates that the increase of 1 dN · m was not attained during the 45 minutes duration of the measurement.

A significant increase in the scorch time is observed with the compositions of the inventions at the operating temperatures of 145° C. and 130° C. compared to the compositions devoid of tung oil, regardless of the used peroxide, while the crosslinking density remains good.

In addition, it can be seen that at the operating temperature of 110° C., very little crosslinking occurs with the compositions of the invention. This is desired because it is preferable that no crosslinking or substantially no crosslinking occurs during the extrusion step for shaping the composition. In contrast, the comparative compositions exhibit a higher crosslinking density à 110° C., which suggests that the presence of tung oil makes it possible to reduce crosslinking at the temperature of 110° C.

When comparing example 20 with examples 18 and 19, no scorch protection was observed when using a castor oil and crosslinking density was even lower than the counterexample without any oil.

1-13. (canceled)

14. A method for curing a curable composition comprising a curable polymer, comprising a step of curing at a temperature of 100° C. or more and in the absence of oxygen, said composition with an organic peroxide formulation comprising:
at least one organic peroxide, and
at least one drying oil,
wherein the weight ratio of the at least one drying oil to the at least one organic peroxide is lower than or equal to 3.

15. The method of claim 14, wherein the at least one drying oil has an iodine value of from 125 to 215 g/100 g.

16. The method of claim 14, wherein the at least one drying oil has a saponification value of from 175 to 210 mg KOH/g.

17. The method of claim 14, wherein the at least one drying oil is selected from the group consisting of tung oil, hemp oil, linseed oil, poppy oil, walnut oil, sunflower oil, cottonseed oil, corn oil, soybean oil, fish oils, herring oil, safflower oil, flax seed oil, perilla oil, oiticica oil, and combinations thereof.

18. The method of claim 14, wherein the at least one organic peroxide is selected from the group consisting of dialkyl peroxides, diperoxyketals, peroxyketals, monoperoxycarbonates, cyclic ketone peroxides, diacyl peroxides, organosulfonyl peroxides, peroxyesters, peroxydicarbonates and combinations thereof.

19. The method of claim 14, wherein the organic peroxide formulation further comprises at least one free radical trap selected from the group consisting of nitroxides, quinones, and mixtures thereof.

20. The method of claim 14, wherein the weight ratio of the at least one drying oil to the at least one organic peroxide is lower than 2.

21. The method of claim 14, wherein the organic peroxide formulation further comprises at least one coagent.

22. The method of claim 14, wherein the at least one polymer is an ethylene polymer.

23. The method of claim 14, wherein the amount of the at least one drying oil in the composition is from 0.005 to 10 parts by weight, for 100 parts by weight of the at least one polymer.

24. A method of preventing scorching of a curable composition during curing, the method comprising curing the curable composition with an organic peroxide formulation comprising at least one organic peroxide and at least one drying oil, wherein the weight ratio of the at least one drying oil to the at least one organic peroxide is lower than or equal to 3, wherein curing is performed at a temperature of 100° C. or more and in the absence of oxygen.

25. The method of claim 18, wherein the at least one organic peroxide is selected from the group consisting of diperoxyketals, peroxyketals, monoperoxycarbonates peroxyesters, and combinations thereof.

26. The method of claim 25, wherein the at least one organic peroxide is selected from the group consisting of OO-t-butyl-O-(2-ethylhexyl)-monoperoxycarbonate, OO-t-butyl-O-2-isopropyl-monoperoxycarbonate, OO-t-amyl-O-(2-ethylhexyl)-monoperoxycarbonate, OO-t-amyl-O-2-isopropyl-monoperoxycarbonate, OO-t-hexyl-O-(2-ethylhexyl)-monoperoxycarbonate and mixtures thereof.

27. The method of claim 21, wherein the at least one coagent is selected from the group consisting of triallyl cyanurate, triallyl isocyanurate, N,N′-m-phenylene dimaleimide, triallyl trimellitate, trimethylolpropane triacrylate, trimethylolpropane trimethacrylate, trivinylcyclohexane and mixtures thereof.
